(19) United States
(12) Patent Application Publication
(10) Pub. No.: US 2023/0417488 A1
(43) Pub. Date: Dec. 28, 2023

(54) HEAT TREATMENT APPARATUS AND TEMPERATURE REGULATION METHOD OF HEAT TREATMENT APPARATUS

(71) Applicant: Tokyo Electron Limited, Tokyo (JP)

(72) Inventors: Makoto TAKAHASHI, Iwate (JP); Kazuteru OBARA, Iwate (JP); Tatsuya YAMAGUCHI, Tokyo (JP)

(21) Appl. No.: 18/210,368

(22) Filed: Jun. 15, 2023

(30) Foreign Application Priority Data
Jun. 27, 2022 (JP) 2022-102990

(51) Int. Cl. F27D 19/00; F27D 7/02

(52) U.S. Cl. CPC F27D 19/00; F27D 7/02; F27D 2019/0053; F27D 2019/0068; F27D 2019/0018

(57) ABSTRACT

A heat treatment apparatus includes: a processing container having an interior space in which substrates are processed; a temperature adjustment furnace that is disposed around the processing container and heats the substrates from the outer side of the processing container; and an internal temperature adjustment unit that is movable relative to the processing container and supplies a temperature adjustment gas for regulating a temperature of the processing container into the interior space in a state of being disposed facing an opening that opens the interior space.

### CROSS-REFERENCE TO RELATED APPLICATIONS

This application is based on and claims priority from Japanese Patent Application No. 2022-102990, filed on Jun. 27, 2022, with the Japan Patent Office, the disclosure of which is incorporated herein in its entirety by reference.

### TECHNICAL FIELD

The present disclosure relates to a heat treatment apparatus and a temperature regulation method of the heat treatment apparatus.

### BACKGROUND

Japanese Patent Laid-Open Publication No. 2007-142237 discloses a substrate processing apparatus (heat treatment apparatus), which accommodates a plurality of substrates in a processing container, and performs a substrate processing such as film formation by supplying a processing gas while heating each substrate.

In order to regulate the temperature of the processing container, this type of heat treatment apparatus heats the processing container from the outer side thereof by using a heater of a heater unit (a temperature adjustment furnace) provided outside the processing container, or cools the processing container from the outer side thereof by supplying air to the interior space of the temperature adjustment furnace. According to requirements of a process condition, the heat treatment apparatus may regulate the temperature of the processing container in the range of, for example, 80° C. to 800° C.

### SUMMARY

According to an aspect of the present disclosure, a heat treatment apparatus includes: a processing container having an interior space, in which substrates are processed; a temperature adjustment furnace disposed around the processing container and configured to heat the substrates accommodated in the interior space from an outer side of the processing container; and an internal temperature adjustment unit movable relative to the processing container and configured to supply a temperature adjustment gas for regulating a temperature of the processing container into the interior space in a state of being disposed facing an opening that opens the interior space.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating a configuration where a plurality of substrates is arranged in a heat treatment apparatus.

FIG. 2 is a schematic view illustrating a configuration where an internal temperature adjustment unit is disposed in the heat treatment apparatus.

FIG. 3 is a flowchart illustrating a temperature regulation method of the heat treatment apparatus.

FIG. 4 is a graph illustrating temperature changes of a processing container in a case where the internal temperature adjustment unit is not used, and in a case where the internal temperature adjustment unit is used.

FIG. 5A is a schematic view illustrating a heat treatment apparatus according to a first modification. FIG. 5B is a schematic view illustrating a heat treatment apparatus according to a second modification.

FIG. 6A is a schematic view illustrating a heat treatment apparatus according to a third modification. FIG. 6B is a schematic view illustrating a heat treatment apparatus according to a fourth modification.

FIG. 7A is a schematic view illustrating an internal temperature adjustment unit according to a fifth modification. FIG. 7B is a schematic view illustrating an internal temperature adjustment unit according to a sixth modification. FIG. 7C is a schematic view illustrating an internal temperature adjustment unit according to a seventh modification.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In the respective drawings, the same components may be denoted by the same reference numerals, and overlapping descriptions thereof may be omitted.

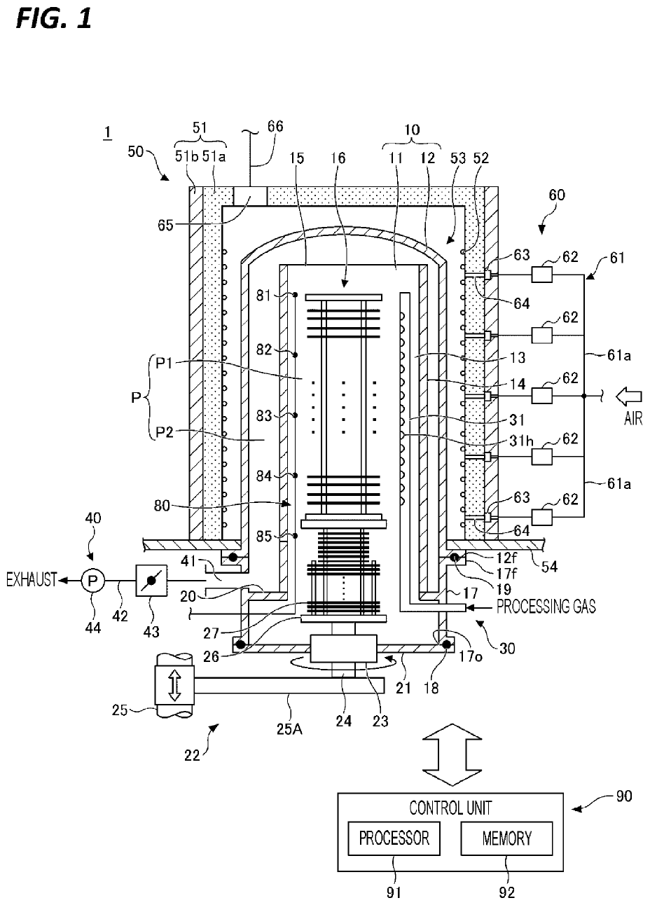

As illustrated in FIG. 1, a heat treatment apparatus 1 according to an embodiment is configured as a vertical type processing apparatus, which arranges a plurality of substrates W vertically (in the up-down direction) in a row, and performs a substrate processing such as film formation on each substrate W. The substrates W may be, for example, semiconductor substrates such as silicon wafers or compound semiconductor wafers, or glass substrates.

The heat treatment apparatus 1 includes a processing container 10 that accommodates the plurality of substrates W therein, and a temperature adjustment furnace 50 disposed around the processing container 10. The heat treatment apparatus 1 further includes a control unit 90 that controls an operation of each component of the heat treatment apparatus 1.

The processing container 10 is formed in a cylindrical shape that extends vertically. Inside the processing container 10 is formed an internal space P, in which the plurality of substrates W may be arranged vertically in a row. The processing container 10 includes, for example, a cylindrical inner cylinder 11 opened at the upper end (ceiling) and the lower end thereof, and a cylindrical outer cylinder 12 disposed outside the inner cylinder and having the ceiling while being opened at the lower end thereof. The inner cylinder 11 and the outer cylinder 12 are made of a heat resistant material such as quartz, and form a double structure by being arranged coaxially with each other. Without being limited to the double structure, the processing container 10 may have a single-cylinder structure or a multiple structure including three or more cylinders.

The inner cylinder 11 has a larger diameter than the diameter of each substrate W, and has an axial length enough to accommodate all of the substrates W (e.g., the height or more, up to which all of the substrates W are arranged). Inside the inner cylinder 11 is formed a processing space P1 where the substrate processing is performed by ejecting a gas to each accommodated substrate W. An opening 15 is provided at the upper end of the inner cylinder 11 to communicate with the processing space P1 and allow the gas to flow out into a distribution space P2 between the inner cylinder 11 and the outer cylinder 12.

At a predetermined circumferential position of the inner cylinder 11, an accommodation portion 13 is provided along the vertical direction to accommodate a gas nozzle 31. For example, the accommodation portion 13 is provided inside a convex portion 14 formed by making a portion of the side wall of the inner cylinder 11 project radially outward. At a predetermined position on the circumferential wall of the inner cylinder 11 (e.g., on the opposite side to the accommodation portion 13 across the central axis), a vertically elongated opening (not illustrated) may be formed.

The outer cylinder 12 has a larger diameter than the inner cylinder 11, covers the inner cylinder 11 in a non-contact manner, and forms the outer shape of the processing container 10. The distribution space P2 between the inner cylinder 11 and the outer cylinder 12 is formed above the inner cylinder 11 and along the lateral side of the inner cylinder 11, and distributes an upwardly moving gas to flow vertically downward. The internal space P of the processing container 10 is configured with the processing space P1 and the distribution space P2.

The lower end of the processing container 10 is supported by a cylindrical manifold 17 formed of, for example, stainless steel. For example, the manifold 17 includes a manifold-side flange 17f at the upper end thereof. The manifold-side flange 17f fixes and supports an outer cylinder-side flange 12f formed at the lower end of the outer cylinder 12. A seal member 19 is provided between the outer cylinder-side flange 12f and the manifold-side flange 17f to airtightly seal the outer cylinder 12 and the manifold 17.

The manifold 17 further includes an annular support 20 on the upper inner wall thereof. The support 20 protrudes radially inward, and fixes and supports the lower end of the inner cylinder 11. A lid 21 is removably mounted at a lower-end opening 17o of the manifold 17.

The lid 21 is configured as a portion of a substrate disposition unit 22 that disposes a wafer boat 16 holding the respective substrates W in the processing container 10. The lid 21 is formed of, for example, stainless steel and has a disk shape. In a state where the respective substrates W are disposed in the processing space P1, the lid 21 airtightly seals the lower-end opening 17o of the manifold 17 via a seal member 18 provided at the lower end of the manifold 17.

A rotary shaft 24 penetrates the center of the lid 21 to rotatably support the wafer boat 16 via a magnetic fluid seal unit 23. The lower portion of the rotary shaft 24 is supported on an arm 25A of a lift mechanism 25 configured with, for example, a boat elevator. By moving the arm 25A of the lift mechanism 25 up and down, the heat treatment apparatus 1 may move the lid 21 and the wafer boat 16 up and down together, thereby inserting and removing the wafer boat 16 into/from the processing container 10.

A rotation plate 26 is provided on the upper end of the rotary shaft 24. The wafer boat 16 holding the respective substrates W is supported on the rotation plate 26 via a heat insulation unit 27. The wafer boat 16 is configured with shelves capable of holding the substrates W vertically at predetermined intervals. In a state where the wafer boat 16 holds the respective substrates W, the surfaces of the substrates W extend horizontally with respect to each other.

A gas supply unit 30 is inserted into the processing container 10 through the manifold 17. The gas supply unit 30 introduces a gas such as a processing gas, a purge gas, and a cleaning gas into the processing space P1 of the inner cylinder 11. For example, the gas supply unit 30 includes a gas nozzle 31 that introduces, for example, the processing gas, the purge gas, and the cleaning gas. While FIG. 1 illustrates only one gas nozzle 31, the gas supply unit 30 may include a plurality of gas nozzles 31. For example, the plurality of gas nozzles 31 may be provided for the respective types of processing gas, purge gas, and cleaning gas.

The gas nozzle 31 is an injector tube made of quartz, and is provided to extend vertically inside the inner cylinder 11 and be bent in an L-shape at the lower end thereof thereby penetrating the manifold 17 from inside to outside. The gas nozzle 31 is fixed to and supported by the manifold 17. The gas nozzle 31 has a plurality of gas holes 31h at predetermined intervals along the vertical direction, and discharges a gas in the horizontal direction through each gas hole 31h. The interval of vertically adjacent gas holes 31h is set to be the same as, for example, the interval of vertically adjacent substrates W supported on the wafer boat 16. The vertical position of each gas hole 31h is set to be located in the middle between vertically adjacent substrates W. As a result, each gas hole 31h may smoothly distribute a gas into the gap between vertically adjacent substrates W.

The gas supply unit 30 supplies, for example, the processing gas, the purge gas, and the cleaning gas to the gas nozzle 31 inside the processing container 10, while controlling the flow rate of the gas outside the processing container 10. An appropriate processing gas may be selected according to a type of film to be formed on the substrates W. For example, when a silicon oxide film is formed, a silicon-containing gas such as dichlorosilane (DCS) gas and an oxidizing gas such as ozone (O₃) gas may be used as the processing gas. As for the purge gas, for example, nitrogen (N₂) gas and argon (Ar) gas may be used.

A gas exhaust unit 40 exhausts the gas inside the processing container 10 to the outside. The gas supplied by the gas supply unit 30 moves from the processing space P1 of the inner cylinder 11 to the distribution space P2, and then, is exhausted through a gas outlet 41. The gas outlet 41 is formed in the upper side wall of the manifold 17 above the support 20. An exhaust path 42 of the gas exhaust unit 40 is connected to the gas outlet 41. The gas exhaust unit 40 includes a pressure regulation valve 43 and a vacuum pump 44 in this order from upstream to downstream of the exhaust path 42. The gas exhaust unit 40 sucks the gas inside the processing container 10 by the vacuum pump 44, and regulates the flow rate of the gas being exhausted by the pressure regulation valve 43, so as to regulate the pressure in the processing container 10.

A temperature sensor 80 is provided inside the processing container 10 (e.g., in the processing space P1 inside the inner cylinder 11) to detect the temperature inside the processing container 10. The temperature sensor 80 includes a plurality of (five in this embodiment) temperature sensors 81 to 85 at different vertical positions. As for the plurality of temperature sensors 81 to 85, for example, thermocouples or resistance thermometers may be used. The temperature sensor 80 transmits the temperature detected by each of the plurality of temperature sensors 81 to 85 to the control unit 90.

Meanwhile, the temperature adjustment furnace 50 is formed in a cylindrical shape covering the entire processing container 10, and heats and cools each substrate W accommodated in the processing container 10. Specifically, the temperature adjustment furnace 50 includes a cylindrical housing 51 having a ceiling, and a heater 52 provided inside the housing 51.

The housing 51 is formed larger than the processing container 10, and its central axis is located at substantially the same position as the central axis of the processing container 10. For example, the housing 51 is attached to the upper surface of a base plate 54, to which the outer cylinder-side flange 12f is fixed. The housing 51 is installed while being spaced apart from the outer peripheral surface of the processing container 10, so that a temperature adjustment space 53 is formed between the outer peripheral surface of the processing container 10 and the inner peripheral surface of the housing 51. The temperature adjustment space 53 is provided to be continuous outside the lateral side of the processing container 10 and above the processing container 10.

The housing 51 includes a heat insulation unit 51a that has a ceiling and covers the entire processing container 10, and a reinforcement unit 51b that reinforces the heat insulation unit 51a on the outer peripheral side of the heat insulation unit 51a. That is, the sidewall of the housing 51 has the stacked structure of the heat insulation unit 51a and the reinforcement unit 51b. The heat insulation unit 51a is formed mainly of, for example, silica or alumina, which suppresses a heat transfer inside the heat insulation unit 51a. The reinforcement unit 51b is formed of a metal such as stainless steel. In order to suppress a heat influence on the outside of the temperature adjustment furnace 50, the outer peripheral side of the reinforcement unit 51b is covered with a water-cooled jacket (not illustrated).

The heater 52 of the temperature adjustment furnace 50 may adopt an appropriate configuration to heat the plurality of substrates W in the processing container 10. As the heater, for example, an infrared heater may be used, which radiates infrared rays to heat the processing container 10. In this case, the heater 52 is formed in a linear shape, and held in a spiral, ring, arc, shank, or meandering shape via a holding unit (not illustrated) on the inner peripheral surface of the heat insulation unit 51a.

The temperature adjustment furnace 50 further includes an external distribution unit 60 that distributes a cooling gas into the temperature adjustment space 53 to cool the processing container 10 during or after the substrate processing. The cooling gas distributed in the temperature adjustment space 53 is air in this embodiment, but is not particularly limited. For example, an inert gas may be applied. Specifically, the external distribution unit 60 includes an external supply line 61 and flow rate regulators 62, which are provided outside the temperature adjustment furnace 50, supply flow paths 63 provided in the reinforcement unit 51b, and supply holes 64 provided in the heat insulation unit 51a.

The external supply line 61 is connected to a blower (not illustrated), which supplies air toward the temperature adjustment furnace 50. In the external supply line 61, a temperature regulation unit (e.g., a heat exchanger or a radiator) may be provided to regulate the temperature of the air that is to flow into the temperature adjustment space 53. The external supply line 61 branches into a plurality of branch lines 61a at intermediate positions. The plurality of branch lines 61a are aligned vertically and connected to the reinforcement unit 51b of the housing 51. Each branch line 61a divides the air supplied from the blower, along the vertical direction.

The flow rate regulators 62 are provided in the plurality of branch lines 61a, respectively, and each regulate the flow rate of the air distributed through each branch line 61a. The plurality of flow rate regulators 62 may each independently change the flow rate of the air under the control of the control unit 90. The flow rate regulators 62 may be configured to regulate the flow rate of the air, for example, manually by a user, without requiring the control unit 90.

The supply flow paths 63 are formed at a plurality of locations along the axial direction of the reinforcement unit 51b (the vertical direction). In a cross-sectional top view, each of the plurality of supply flow paths 63 extends circumferentially in an annular shape inside the cylindrical reinforcement unit 51b.

The respective supply holes 64 are formed in a matrix shape along the axial direction (vertical direction) and the circumferential direction of the heat insulation unit 51a. The supply holes 64 arranged in the axial direction are located at the same axial positions as the supply flow paths 63 arranged in the axial direction, respectively, and communicate with the supply flow paths 63, respectively, along the horizontal direction. Each supply hole 64 is formed to penetrate the heat insulation unit 51a, and ejects the air introduced into each supply flow path 63 toward the temperature adjustment space 53.

The external distribution unit 60 further includes an exhaust hole 65 in the ceiling of the housing 51 to discharge the air supplied into the temperature adjustment space 53. The exhaust hole 65 is connected to an external exhaust line 66 provided outside the housing 51. The external exhaust line 66 exhausts the air of the temperature adjustment space 53 toward an appropriate disposal unit. Alternatively, the external distribution unit 60 may be configured such that the external exhaust line 66 is connected to the external supply line 61 to circulate the air used in the temperature adjustment space 53.

The control unit 90 of the heat treatment apparatus 1 may be a computer including, for example, a processor 91, a memory 92, and an input/output interface (not illustrated). The processor 91 may be one of a central processing unit (CPU), a graphics processing unit (GPU), an application specific integrated circuit (ASIC), a field-programmable gate array (FPGA), and circuits including multiple discrete semiconductors, or a combination thereof. The memory 92 is an appropriate combination of a volatile memory and a non-volatile memory (e.g., a compact disk, a digital versatile disk (DVD), a hard disk, and a flash memory).

The memory 92 stores programs for operating the heat treatment apparatus 1 and recipes such as process conditions for the substrate processing. The processor 91 reads and executes the programs of the memory 92, so as to control each component of the heat treatment apparatus 1. The control unit 90 may be configured with a host computer or multiple client computers, which communicate information via a network.

Here, the heat treatment apparatus 1 may raise the temperature of each substrate W in a short time, by driving the heater 52 of the temperature adjustment furnace 50 during the substrate processing. Meanwhile, when lowering the temperature of the processing container 10, the heat treatment apparatus 1 distributes air by the external distribution unit 60, and therefore, drops the temperature over a long period of time. Since it takes a long time to lower the temperature of the processing container 10, the throughput of the overall substrate processing is deteriorated. In particular, in recent years, the heat treatment apparatus 1 has been required to perform the substrate processing, the preparation for the substrate processing, and the follow-up process of the substrate processing in a broad temperature range (e.g., 80° C. to 800° C.), and has also been required to quickly regulate the temperature to a target temperature.

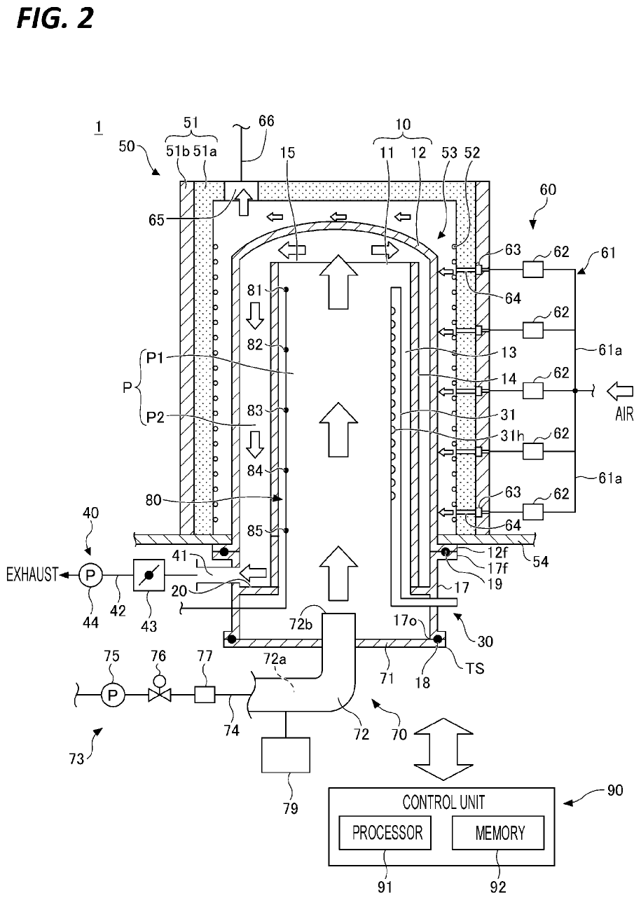

For this reason, as illustrated in FIG. 2, the heat treatment apparatus 1 according to the present embodiment includes an internal temperature adjustment unit 70 that cools the internal space P of the processing container 10. The internal temperature adjustment unit 70 is an apparatus that is mounted in the processing container 10 in a state where the substrate disposition unit 22 having the wafer boat 16 is removed from the processing container 10.

The internal temperature adjustment unit 70 includes a facing member 71 that is positioned facing the lower-end opening 17o of the manifold 17, a temperature adjustment gas supply pipe 72 fixed to the facing member 71, and an external supply unit 73 connected to the temperature adjustment gas supply pipe 72. The internal temperature adjustment unit 70 further includes a unit operation part 79 that moves the facing member 71 and the temperature adjustment gas supply pipe 72 together relative to the processing container 10.

A temperature adjustment gas supplied by the internal temperature adjustment unit 70 is not particularly limited, and may be, for example, air or an inert gas (e.g., CO₂, N₂, or Ar). In the present embodiment, air is used as the temperature adjustment gas, and the external supply unit 73 adopts, for example, a mechanism that collects and force-feeds the room air. Further, the internal temperature adjustment unit 70 may include a temperature regulation unit (e.g., a heat exchanger or a radiator) that regulates the temperature of the air during the introduction of the air into the interior space P of the processing container 10.

Similar to the lid 21 of the substrate disposition unit 22, the facing member 71 of the internal temperature adjustment unit 70 is removable with respect to the lower-end opening 17o of the manifold 17. The facing member 71 is moved by the unit operation part 79 to a temperature adjustment position TS for closing the lower-end opening 17o of the manifold 17, or a retreat position (not illustrated) away from the lower-end opening 17o to move the substrate disposition unit 22 to the lower-end opening 17o of the manifold 17. The facing member 71 is formed of, for example, stainless steel and has a disk shape. The facing member 71 also is capable of airtightly sealing the lower-end opening 17o of the manifold 17 via the seal member 18.

The temperature adjustment gas supply pipe 72 is formed of, for example, a hard metal pipe, and attached to the center of the facing member 71. The temperature adjustment gas supply pipe 72 has a larger diameter than the gas nozzle 31, and includes a flow path 72a where air may be distributed in a large flow rate. The temperature adjustment gas supply pipe 72 protrudes linearly on the upper side of the facing member 71. At the upper end (protruding end) of the temperature adjustment gas supply pipe 72 is provided an ejection port 72b communicating with the flow path 72a and capable of ejecting the air. Further, the temperature adjustment gas supply pipe 72 may be provided at a position out of the center of the facing member 71 (the axial center of the processing container 10).

The temperature adjustment gas supply pipe 72 is bent substantially in an L shape on the lower side of the facing member 71, and connected to the external supply unit 73. The external supply unit 73 includes a distribution line 74 connected to the temperature adjustment gas supply pipe 72. At least a portion of the distribution line 74 is configured with a flexible tube, which enables the movement of the facing member 71 and the temperature adjustment gas supply pipe 72 by the unit operation part 79. In the distribution line 74, a supply pump 75, an opening/closing valve 76, and a flow rate regulator 77 are provided in this order from upstream to downstream along the distribution direction of the air.

The supply pump 75 operates under the control of the control unit 90, to force-feed the air toward the downstream side of the distribution line 74. The opening/closing valve 76 opens and closes the flow path of the distribution line 74 under the control of the control unit 90, thereby switching the supply of the air into the processing container 10 and the stop of the supply. The flow rate regulator 77 operates under the control of the control unit 90, to regulate the flow rate of the air supplied into processing container 10.

The flow rate of the air supplied into the processing container 10 by the internal temperature adjustment unit 70 (the flow rate regulator 77) varies according to, for example, the size of the processing container 10, but may be within the range of, for example, 100 SLM to 2,000 SLM. Meanwhile, the flow rate of the processing gas or the purge gas supplied into the processing container 10 through the gas nozzle 31 during the substrate processing is, for example, about 10 SLM. Accordingly, the supply amount of air supplied into the internal space P by the internal temperature adjustment unit 70 is sufficiently larger than the supply amount of processing gas or purge gas supplied by the gas nozzle 31. Therefore, the heat treatment apparatus 1 may efficiently lower the temperature inside the processing container 10. For example, the supply amount of air may be set in the range of 5 times to 200 times the supply amount of processing gas or purge gas. When this rate is less than 5 times, it may be difficult to lower the temperature of the processing container 10, and when this rate is more than 200 times, it may not be possible to exhaust the air smoothly from the processing container 10.

The unit operation part 79 of the internal temperature adjustment unit 70 supports an appropriate location of the facing member 71 and the temperature adjustment gas supply pipe 72, and moves these members together. The unit operation part 79 includes a drive source (not illustrated) such as a motor, and a drive transmission mechanism (not illustrated), and moves the facing member 71 and the temperature adjustment gas supply pipe 72 between the temperature adjustment position TS and the retreat position according to a driving power of the drive source.

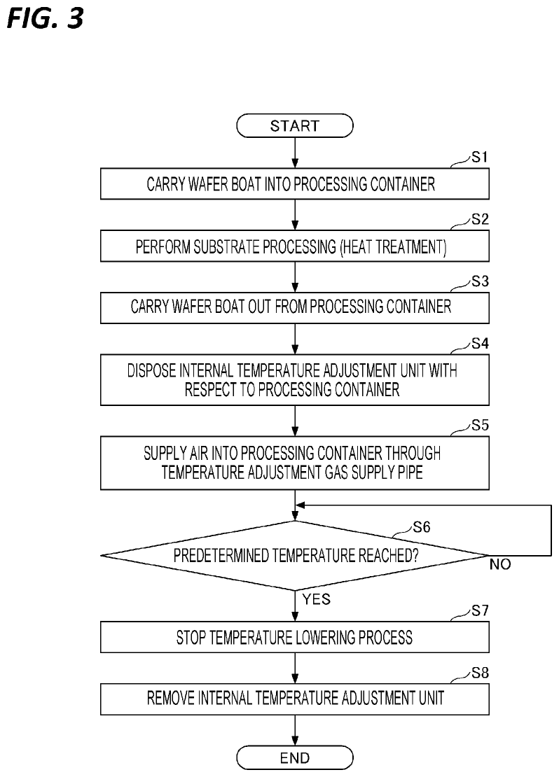

The heat treatment apparatus 1 according to the present embodiment is basically configured as described above, and the operation thereof (a temperature regulation method of the heat treatment apparatus 1) is described below with reference to FIG. 3.

In preparing for the substrate processing, the control unit 90 of the heat treatment apparatus 1 first moves the substrate disposition unit 22 to carry the wafer boat 16 holding the respective substrates W into the processing container 10 (step S1). Following the carry-in of the wafer boat 16, the lid 21 closes the lower-end opening 17o of the manifold 17, such that the internal space P of the processing container 10 is sealed.

Then, the heat treatment apparatus 1 performs the substrate processing on each substrate W. For example, when a film formation is performed, the heat treatment apparatus 1 performs a heat treatment for controlling the heater 52 of the temperature adjustment furnace 50 to raise the temperature to a set temperature and heat the respective substrates W in the processing container 10 to a temperature required for the film formation (step S2). Further, in the substrate processing, the heat treatment apparatus 1 controls the operation of the gas supply unit 30 to supply the processing gas into the processing container 10 through the gas nozzle 31, and simultaneously, exhausts the processing gas in the processing container 10 by the gas exhaust unit 40. As a result, the heat treatment apparatus 1 is sufficiently filled with the processing gas in a state where the pressure in the processing container 10 is maintained at a set pressure, and a film is formed on the surface of each heated substrate W. The heat treatment apparatus 1 may change the temperature of each substrate W or the type of processing gas during the substrate processing, to stack multiple films or perform, for example, an oxidation or nitridation of a film.

After the substrate processing, the control unit 90 moves the substrate disposition unit 22 to carry out the wafer boat 16 from the inside of the processing container 10 (step S3). As a result, the lower-end opening 17o of the processing container 10 (the manifold 17) is opened. At this time, as the driving of the heater 52 of the temperature adjustment furnace 50 is stopped, the temperature inside the processing container 10 lowers from the temperature at the time of the substrate processing. However, the decrease of the temperature inside the processing container 10 progresses slowly.

After the wafer boat 16 is retreated, in order to perform a temperature lowering process, the control unit 90 controls the unit operation part 79 to move the internal temperature adjustment unit 70 and dispose the facing member 71 and the temperature adjustment gas supply pipe 72 at the temperature adjustment position TS (step S4). As a result of this disposition, the facing member 71 closes the lower-end opening 17o of the manifold 17, so that the internal space P of the processing container 10 is sealed.

Then, for the temperature lowering process, the control unit 90 controls the external supply unit 73 to supply the air as the temperature adjustment gas from the outside of the processing container 10 into the internal space P of the processing container 10 through the temperature adjustment gas supply pipe 72 (step S5). At this time, the external supply unit 73 continuously supplies the air in a large flow rate (e.g., 1,000 SLM) into the processing container 10. As illustrated in FIG. 2, the air supplied by the external supply unit 73 flows into the processing space P1 from the ejection port 72b of the temperature adjustment gas supply pipe 72 and moves upward in the processing space P1 while cooling the inner cylinder 11. The air passes through the opening 15 of the inner cylinder 11, moves into the upper distribution space P2, and moves downward in the lateral distribution space P2 (on the side of the outer periphery of the inner cylinder 11). Further, the air moves while cooling the inner cylinder 11 and the outer cylinder 12, and flows out to the exhaust path 42 from the gas outlet 41 of the manifold 17.

The gas exhaust unit 40 exhausts the air that has cooled the inner cylinder 11 and the outer cylinder 12, through the exhaust path 42. At this time, the gas exhaust unit 40 may control the operations of the pressure regulation valve 43 and the vacuum pump 44 in accordance with the supply amount of air supplied into the internal space P, so that the gas in the processing container 10 may be exhausted stably.

In the temperature lowering process, the control unit 90 cools the outer side of the processing container 10 by the external distribution unit 60 provided in the temperature adjustment furnace 50, in parallel with the cooling of the inside of the processing container 10 by the internal temperature adjustment unit 70. At this time, the control unit 90 supplies the air as the cooling gas from a blower through the external supply line 61, and introduces the air into the temperature adjustment space 53 from each supply hole 64 while regulating the flow rate of the air with each flow rate regulator 62. As a result, the processing container 10 is also cooled by the air that is being distributed outside, so that the cooling efficiency is further improved. The timing for cooling the outer side of the processing container 10 (the operation of the external distribution unit 60) is not limited to step S5, but the cooling may be performed, for example, from the time when the wafer boat 16 is carried out in step S3. Alternatively, when a temperature lowering step is performed during the heat treatment, the air may be continuously supplied from step S2.

Referring back to FIG. 3, while performing the temperature lowering process of supplying the air into the internal space P, the control unit 90 determines whether the temperature inside the processing container 10 has reached a predetermined set temperature (step S6). The temperature of the internal space P may be identified using detection information obtained from the detection by the temperature sensor 80. The control unit 90 continues the temperature lowering process until the temperature inside the processing container 10 reaches the set temperature, and proceeds with step S7 when the temperature inside the processing container 10 reaches the set temperature (step S6: YES).

In step S7, the control unit 90 performs a process of stopping the temperature lowering process. At this time, the control unit 90 stops the supply of air by the external supply unit 73 and also stops the supply of air by the external distribution unit 60 of the temperature adjustment furnace 50.

Then, when the temperature lowering process is terminated, the control unit 90 controls the unit operation part 79 to remove the facing member 71 and the temperature adjustment gas supply pipe 72 from the lower-end opening 17o of the manifold 17 (step S8). Accordingly, the heat treatment apparatus 1 is brought into a state of being ready to carry the wafer boat 16 holding the respective substrates W to be processed next, into the processing container 10.

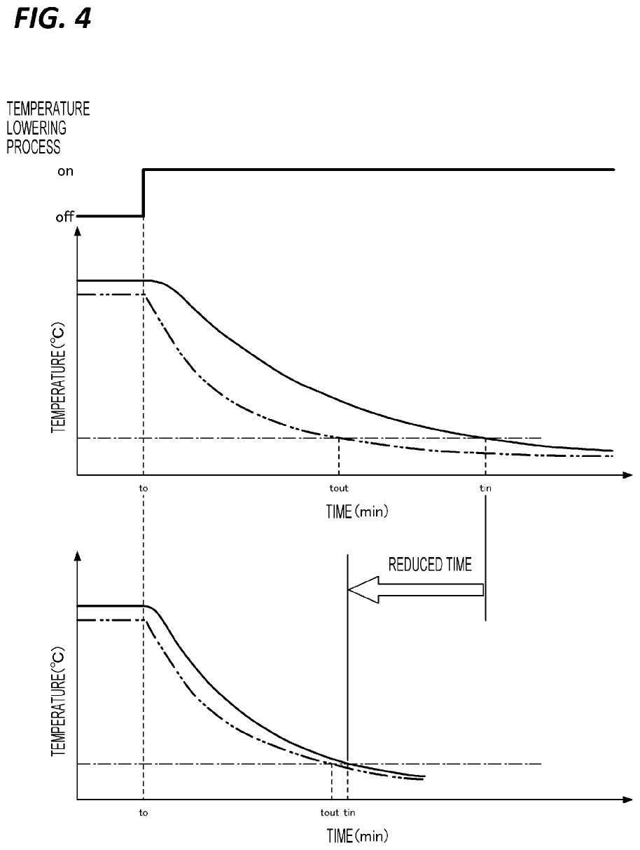

Next, descriptions will be made on effects resulting from the supply of air from the internal temperature adjustment unit 70 into the processing container 10, with reference to FIG. 4. The upper graph of FIG. 4 represents a time elapse and a temperature change of the processing container 10, in a case where air is not supplied into the processing container 10. The lower graph of FIG. 4 represents a time elapse and a temperature change of the processing container 10, in a case where air is supplied into the processing container 10. However, in both the case where air is not supplied into the processing container 10 and the case where air is supplied into the processing container 10, a control is performed to distribute air in the temperature adjustment space 53 of the temperature adjustment furnace 50, and thus, the processing container 10 is cooled from outside.

As can be seen from FIG. 4, the temperature of the inner cylinder 11 and the temperature of the outer cylinder 12 both lower from the start timing of the temperature lowering process. Here, in a case where air is not supplied into the processing container 10, the processing container 10 is cooled from its outer side (the outer cylinder 12) by the air supplied into the temperature adjustment space 53. Accordingly, in the upper graph, the temperature of the inner cylinder 11 (see the solid line in FIG. 4) lowers slowly at a slower lowering rate than the temperature of the outer cylinder 12 (see the alternate long and two dashed line in FIG. 4).

The temperature of the outer cylinder 12 reaches the set temperature (e.g., 80° C.) for the temperature lowering process at a timing tₒᵤₜ. Meanwhile, the temperature of the inner cylinder 11 reaches the set temperature for the temperature lowering process at a timing tᵢₙ, which is much later than the timing tₒᵤₜ. That is, in a case where air is not supplied into the processing container 10, the difference between the temperature of the inner cylinder 11 and the temperature of the outer cylinder 12 becomes large, and as a result, the temperature of the entire processing container 10 drops late.

In contrast, the heat treatment apparatus 1 according to the present embodiment may directly cool the inside of the processing container 10 by supplying air into the processing container 10 using the internal temperature adjustment unit 70. The heat treatment apparatus 1 may also cool the outer side of the processing container 10 by supplying air into the temperature adjustment space 53 of the external distribution unit 60.

As a result, the timing tᵢₙ, at which the temperature of the inner cylinder 11 reaches the set temperature is sufficiently close to the temperature tₒᵤₜ, at which the temperature of the outer cylinder 12 reaches the set temperature. In other words, the heat treatment apparatus 1 may lower the temperature of the inner cylinder 11 and the temperature of the outer cylinder 12 at around the same time. Therefore, the heat treatment apparatus 1 may adjust the temperature of the processing container 10 in a short time by the internal temperature adjustment unit 70, so that the throughput of the overall substrate processing may be largely improved. Further, in the heat treatment apparatus 1, the uniformity between the temperature of the inner cylinder 11 and the temperature of the outer cylinder 12 is expedited, so that the temperature of the entire processing container 10 may be precisely adjusted to a target temperature.

The heat treatment apparatus 1 and the heat treatment method of the present disclosure are not limited to the embodiment described above, and various modifications may be made thereto. For example, in the temperature lowering process, the heat treatment apparatus 1 may supply air into the processing container 10 by the internal temperature adjustment unit 70, without supplying air into the temperature adjustment space 53 by the external distribution unit 60.

For example, the configuration of the internal temperature adjustment unit 70 is not particularly limited as long as the temperature adjustment gas may be supplied into the internal space P. As another example of the configuration of the embodiment described above, the internal temperature adjustment unit 70 may include a plurality of temperature adjustment gas supply pipes 72. In this case, the respective temperature adjustment gas supply pipes 72 may be arranged circumferentially in the vicinity of the inner peripheral surface of the inner cylinder 11. Further, the configuration of the temperature adjustment gas supply pipe 72 is not limited to the configuration where the temperature adjustment gas is ejected vertically (along the axis center of the inner cylinder 11), but the temperature adjustment gas may be ejected obliquely to the vertical direction or in a tornado shape.

Further, the heat treatment apparatus 1 is not limited to using the internal temperature adjustment unit 70 for lowering the temperature of the processing container 10, but may apply the internal temperature adjustment unit 70 to raising the temperature of the processing container 10. For example, the internal temperature adjustment unit 70 assists in raising the temperature of the processing container 10 by supplying a hot temperature adjustment gas into the processing container 10 while heating the processing container 10 by the heater 52 of the temperature adjustment furnace 50. As a result, the temperature of the processing container 10 may be raised in a short time.

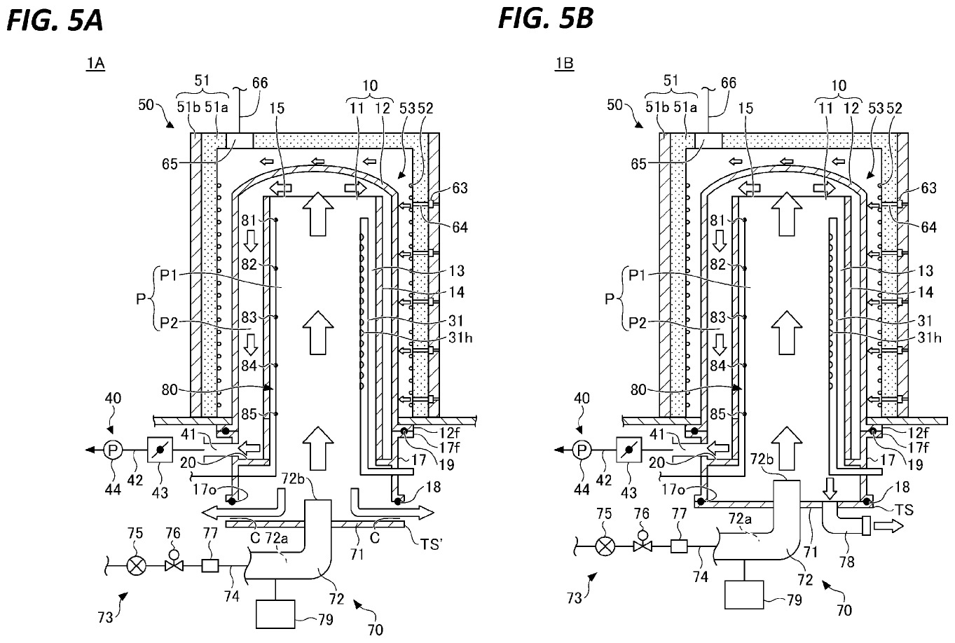

Descriptions will be made on a heat treatment apparatus 1 and a heat treatment method according to some other modifications, with reference to FIGS. 5 to 7.

A heat treatment apparatus 1A according to a first modification illustrated in FIG. 5A is different from the heat treatment apparatus 1 above, in that the heat treatment apparatus 1A performs the temperature lowering process without bringing the lower end of the manifold 17 and the facing member 71 of the internal temperature adjustment unit 70 into contact with each other. That is, the heat treatment apparatus 1A sets a temperature adjustment position TS' for the temperature lowering process at a position spaced apart downward from the lower end of the manifold 17. The unit operation part 79 moves the facing member 71 and the temperature adjustment gas supply pipe 72 between the temperature adjustment position TS' and the retreat position.

A clearance C is formed between the facing member 71 disposed at the temperature adjustment position TS' and the lower end of the manifold 17. During the temperature lowering process, part of the air supplied from the temperature adjustment gas supply pipe 72 is discharged through the clearance C. That is, the air ejected from the ejection port 72b of the temperature adjustment gas supply pipe 72 moves upward at the center of the processing space P1, and is exhausted from the gas exhaust unit 40 through the distribution space P2. When the exhaust by the gas exhaust unit 40 does not keep up with the supply amount of air, the air moves downward near the inner wall of the inner cylinder 11 and is discharged to the outside through the clearance C.

As a result, the heat treatment apparatus 1A may suppress the deterioration of cooling efficiency resulting from the increasing pressure of the processing container 10 during the temperature lowering process, so that the temperature lowering process may be more efficiently performed. The configuration of exhausting the air supplied into the processing container 10 to the outside during the temperature lowering process is not limited to the configuration described above, and various configurations may be adopted. For example, one or more holes may be formed in the facing member 71 such that the air may be exhausted to the outside through the holes. Further, without including the facing member 71, the internal temperature adjustment unit 70 may move only the temperature adjustment gas supply pipe 72 to be inserted into the internal space P from the lower-end opening 17o.

In a heat treatment apparatus 1B according to a second modification illustrated in FIG. 5B, an exhaust pipe 78 (an exhaust unit) is provided in the facing member 71, separately from the temperature adjustment gas supply pipe 72. With the exhaust pipe 78 as well, the heat treatment apparatus 1B may smoothly exhaust the air supplied into the processing container 10 to the outside in the same manner as the clearance C. Further, the air of which temperature has raised in the processing container 10 may be induced to an appropriate disposal unit through the exhaust pipe 78 and an exhaust path (not illustrated).

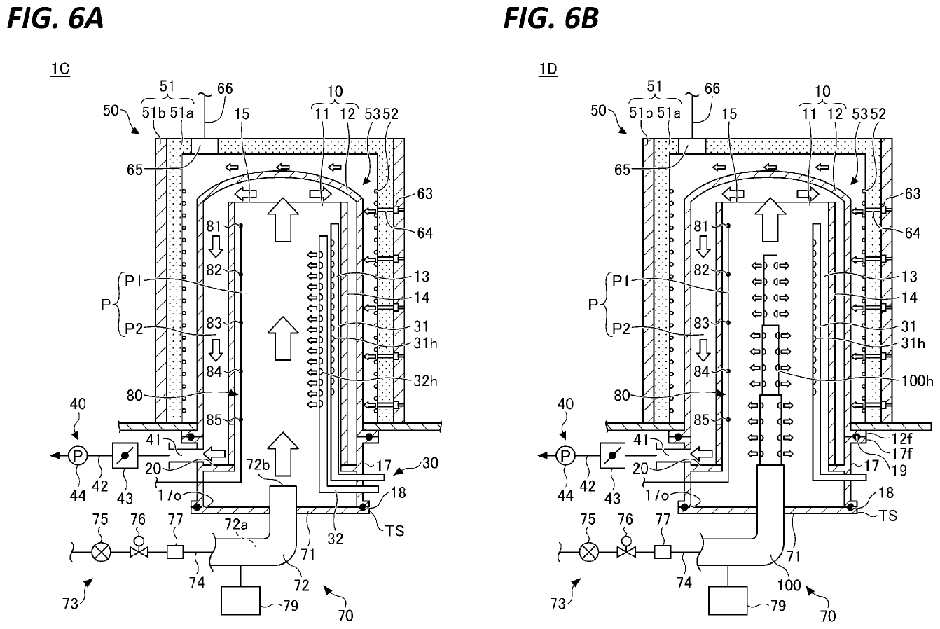

A heat treatment apparatus 1C according to a third modification illustrated in FIG. 6A is different from the heat treatment apparatus 1 above, in that the heat treatment apparatus 1C supplies the temperature adjustment gas (air or inert gas) by the gas supply unit 30 during the temperature lowering process, further to supplying the air into the processing container 10 from the temperature adjustment gas supply pipe 72. For example, the heat treatment apparatus 1C includes a sub temperature adjustment gas supply pipe 32 that ejects the temperature adjustment gas, separately from the gas nozzle 31. The sub temperature adjustment gas supply pipe 32 has a plurality of ejection holes 32h in its portion extending vertically inside the processing container 10, and a portion bent from the extending portion is fixed to the manifold 17.

As a result, in the heat treatment apparatus 1C, the air may be supplied from both the temperature adjustment gas supply pipe 72 and the sub temperature adjustment gas supply pipe 32 during the temperature lowering process, so that the inside of the processing container 10 may be more efficiently cooled. In FIG. 6A, the sub temperature adjustment gas supply pipe 32 is provided separately from the gas nozzle 31. However, the heat treatment apparatus 1C may supply the temperature adjustment gas by using the gas nozzle 31.

A heat treatment apparatus 1D according to a fourth modification illustrated in FIG. 6B is different from the heat treatment apparatus 1, in that the heat treatment apparatus 1D includes a telescopic internal supply pipe 100. The internal supply pipe 100 is shortened when it moves, and vertically lengthened in the processing space P1 during the temperature lowering process. The internal supply pipe 100 ejects the air from a plurality of ejection holes 100h provided in the lateral side thereof. As a result, the internal supply pipe 100 may eject the air directly to the inner cylinder 11, so that the residual heat of the inner cylinder 11 may be effectively reduced. Thus, the heat treatment apparatus 1D may smoothly lower the temperature inside the processing container 10.

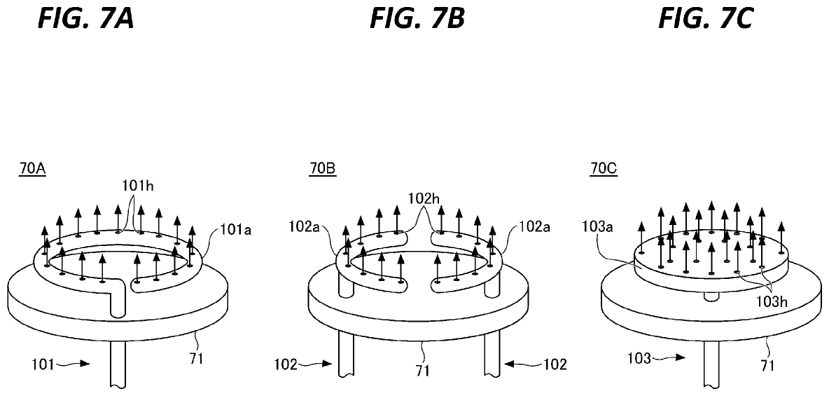

An internal temperature adjustment unit 70A according to a fifth modification illustrated in FIG. 7A includes a temperature adjustment gas supply pipe 101 that ejects the temperature adjustment gas vertically upward in the vicinity of the inner peripheral surface of the inner cylinder 11. Specifically, the temperature adjustment gas supply pipe 101 includes an ejection pipe 101a formed circumferentially in a C shape on the same horizontal plane above the facing member 71 (in the internal space P). The ejection pipe 101a has a plurality of ejection holes 101h formed along the circumferential direction and communicating with the inside flow path thereof. As a result, the temperature adjustment gas supply pipe 101 may smoothly eject the temperature adjustment gas from the plurality of ejection holes 101h along the vicinity of the inner peripheral surface of the inner cylinder 11 (in parallel to the axial center of the inner cylinder 11), so that the residual heat of the inner cylinder 11 may more smoothly be reduced.

An internal temperature adjustment unit 70B according to a sixth modification illustrated in FIG. 7B includes a plurality of (two) temperature adjustment gas supply pipes 102 that ejects the temperature adjustment gas vertically upward in the vicinity of the inner peripheral surface of the inner cylinder 11. Each temperature adjustment gas supply pipe 102 includes an ejection pipe 102a formed circumferentially in an arc shape on the same horizontal plane, and a plurality of ejection holes 102h is formed in the upper surface of each ejection pipe 102a. In this case as well, the internal temperature adjustment unit 70B may eject the temperature adjustment gas from the plurality of ejection holes 102h along the vicinity of the inner peripheral surface of the inner cylinder 11 (in parallel to the axis center of the inner cylinder 11), so that the temperature inside the processing container 10 may be smoothly lowered.

An internal temperature adjustment unit 70C according to a seventh modification illustrated in FIG. 7C adopts a temperature adjustment gas supply pipe 103 provided with a shower head 103a above the facing member 71. A plurality of ejection holes 103h is provided in the upper surface of the shower head 103a to eject the temperature adjustment gas vertically upward. The temperature adjustment gas supply pipe 103 having this configuration may uniformly eject the temperature adjustment gas in the substantially whole space inside the inner cylinder 11, so that it may be expected to uniformly lower the temperature inside the processing container 10.

The technical idea and effects of the present disclosure described in the foregoing embodiments are described below.

According to a first aspect of the present disclosure, heat treatment apparatuses 1 and 1A to 1D include: a processing container 10 having an interior space P, in which substrates W are processed; a temperature adjustment furnace 50 that is disposed around the processing container 10 and heats the substrates W accommodated in the interior space P from an outer side of the processing container 10; and an internal temperature adjustment unit 70 that is movable relative to the processing container 10 and supplies a temperature adjustment gas for regulating a temperature of the processing container 10 into the interior space P in a state of being disposed facing an opening (the lower-end opening 170) that opens the interior space P.

According to this configuration, the heat treatment apparatuses 1 and 1A to 1D may efficiently regulate the temperature of the processing container 10 by the internal temperature adjustment unit 70. For example, even when the processing container 10 that has been heated by the temperature adjustment furnace 50 is shifted from the high temperature state to a low temperature, the temperature of the processing container 10 may be lowered in a short time. As a result, the heat treatment apparatuses 1 and 1A to 1D may largely improve the throughput of the overall substrate processing.

The internal temperature adjustment unit 70 includes a facing member 71 movable to face the opening (the lower-end opening 170), and a temperature adjustment gas supply pipe 72 that is fixed to the facing member 71 and moves together with the facing member 71 to eject the temperature adjustment gas into the interior space P. As a result, the internal temperature adjustment unit 70 may smoothly supply the temperature adjustment gas in a large flow rate from the opening toward the interior space P.

The temperature adjustment gas supply pipe 72 has an ejection port 72b that ejects the temperature adjustment gas along (in parallel to) an axial center of the processing container 10. As a result, the internal temperature adjustment unit 70 may eject the temperature adjustment gas into the center of the interior space P, so that the temperature adjustment gas may spread throughout the entire processing container 10, and the uniformity of temperature distribution may be expedited.

The internal temperature adjustment unit 70 moves relative to the processing container to dispose the facing member 17 at a position where the opening (the lower-end opening 170) is closed, and ejects the temperature adjustment gas in a state where the opening is closed. As a result, the heat treatment apparatuses 1 and 1B to 1D may efficiently adjust the temperature of the processing container 10 by effectively using the temperature adjustment gas supplied into the processing container 10.

The internal temperature adjustment unit 70 moves relative to the processing container 10 to dispose the facing member 71 at a position spaced apart from the opening (the lower-end opening 170), and ejects the temperature adjustment gas in a state where a clearance C is formed between the opening and the facing member 71. As a result, the heat treatment apparatus 1A may exhaust the temperature adjustment gas of the processing container 10 from the clearance C, so that the temperature of the processing container 10 may be regulated in a shorter time by supplying the temperature adjustment gas in a large flow rate.

The internal temperature adjustment unit 70 includes an exhaust unit (the exhaust pipe 78), in the facing member 71, capable of exhausting a gas of the interior space P. As a result, the heat treatment apparatus 1B may exhaust the temperature adjustment gas of the processing container 10 from the exhaust unit, so that the temperature adjustment gas may be smoothly discarded.

The heat treatment apparatuses 1 and 1A to 1D further include: a gas nozzle 31 that supplies a processing gas for processing the substrates W into the interior space P, and the internal temperature adjustment unit 70 supplies the temperature adjustment gas in a larger supply amount than a supply amount of the processing gas. As a result, the heat treatment apparatuses 1 and 1A to 1D may adjust the temperature of the processing container in a much shorter time.

The heat treatment apparatuses 1 and 1A to 1D further include: a manifold 17 that supports the processing container 10 at a lower end of the processing container 10, and has a lower end at which the opening (the lower-end opening 170) is formed; and a substrate disposition unit 22 that has a wafer boat 16 that holds a plurality of substrates W, and moves relative to the manifold 17 to insert the wafer boat 16 into the interior space P through the opening, and when the temperature of the processing container 10 is regulated, the substrate disposition unit 22 retreats from the processing container 10, and the internal temperature adjustment unit 70 is disposed facing the opening. By replacing the substrate disposition unit 22 with the internal temperature adjustment unit 70 after the heat treatment, the heat treatment apparatuses 1 and 1A to 1D may quickly lower the temperature of the processing container that has been heated to the high temperature.

The heat treatment apparatus 1C further includes: a sub temperature adjustment gas supply pipe that is supported on the manifold 17, and supplies the temperature adjustment gas into the interior space P separately from the internal temperature adjustment unit 70. As a result, the heat treatment apparatus 1C may more quickly lower the temperature of the processing container 10.

The heat treatment apparatuses 1 and 1A to 1D further include: a control unit 90 that controls operations of the temperature adjustment furnace 50 and the internal temperature adjustment unit 70, and the control unit 90 performs a temperature lowering process to lower the temperature of the processing container 10 by supplying the temperature adjustment gas from the internal temperature adjustment unit 70 into the interior space P after a heating of the substrates W by the temperature adjustment furnace 50 is stopped. As a result, the heat treatment apparatuses 1 and 1A to 1D may smoothly start the temperature lowering process after the heat treatment.

A temperature adjustment space 53 is formed between the temperature adjustment furnace 50 and the processing container 10, the temperature adjustment furnace 50 includes an external distribution unit 60 that distributes a cooling gas in the temperature adjustment space 53, and during the temperature lowering process, the control unit 90 performs supplying the temperature adjustment gas into the interior space P by the internal temperature adjustment unit 70 and distributing the cooling gas in the temperature adjustment space by the external distribution unit 60. As a result, the heat treatment apparatuses 1 and 1A to 1D may cool the processing container 10 from both the inner and outer sides thereof, so that the temperature of the processing container 10 may be even more efficiently lowered.

According to a second aspect of the present disclosure, a temperature regulation method includes: (a) providing heat treatment apparatuses 1 and 1A to 1D equipped with a processing container 10 having an interior space P, in which substrates W are processed; (b) heating the substrates W accommodated in the interior space P from an outer side of the processing container 10 by a temperature adjustment furnace 50 disposed around the processing container 10; and (c) moving an internal temperature adjustment unit 70 relative to the processing container 10 to dispose the internal temperature adjustment unit 70 to face an opening (the lower-end opening 170) that opens the interior space P; and (d) in a state where the internal temperature adjustment unit 70 is disposed facing the opening, supplying a temperature adjustment gas for regulating a temperature of the processing container 10 into the interior space P. As a result, the temperature regulation method may efficiently regulate the temperature of the processing container 10, so that the throughput of the overall substrate processing may be improved.

According to an aspect of the present disclosure, the temperature of a processing container may be efficiently regulated.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A heat treatment apparatus comprising:
a processing container having an interior space in which substrates are processed;
a temperature adjustment furnace disposed around the processing container and configured to heat the substrates accommodated in the interior space from an outer side of the processing container; and
an internal temperature adjustment block movable relative to the processing container and configured to supply a temperature adjustment gas for regulating a temperature of the processing container into the interior space in a state of being disposed facing an opening that opens the interior space.

2. The heat treatment apparatus according to claim 1, wherein the internal temperature adjustment block includes
a facing plate movable to face the opening, and
a temperature adjustment gas supply pipe fixed to the facing plate and configured to move together with the facing plate to eject the temperature adjustment gas into the interior space.

3. The heat treatment apparatus according to claim 2, wherein the temperature adjustment gas supply pipe has an ejection port that ejects the temperature adjustment gas along an axial center of the processing container.

4. The heat treatment apparatus according to claim 2, wherein the internal temperature adjustment block moves relative to the processing container to dispose the facing plate at a position where the opening is closed, and ejects the temperature adjustment gas in a state where the opening is closed.

5. The heat treatment apparatus according to claim 2, wherein the internal temperature adjustment block moves relative to the processing container to dispose the facing plate at a position spaced apart from the opening, and ejects the temperature adjustment gas in a state where a clearance is formed between the opening and the facing plate.

6. The heat treatment apparatus according to claim 2, wherein the internal temperature adjustment block includes an exhaust provided in the facing plate and configured to exhaust a gas of the interior space.

7. The heat treatment apparatus according to claim 1, further comprising:
a gas nozzle configured to supply a processing gas for processing the substrates into the interior space,
wherein the internal temperature adjustment block supplies the temperature adjustment gas in a larger supply amount than a supply amount of the processing gas.

8. The heat treatment apparatus according to claim 1, further comprising:
a manifold configured to support the processing container at a lower end of the processing container, and having a lower end at which the opening is formed; and
a substrate disposition unit having a wafer boat that holds a plurality of substrates, and configured to move relative to the manifold to insert the wafer boat into the interior space through the opening,
wherein when the temperature of the processing container is regulated, the substrate disposition unit retreats from the processing container, and the internal temperature adjustment block is disposed facing the opening.

9. The heat treatment apparatus according to claim 8, further comprising:
a sub temperature adjustment gas supply pipe supported on the manifold, and configured to supply the temperature adjustment gas into the interior space separately from the internal temperature adjustment unit.

10. The heat treatment apparatus according to claim 1, further comprising:
a controller configured to control operations of the temperature adjustment furnace and the internal temperature adjustment block,
wherein the controller performs a temperature lowering process to lower the temperature of the processing container by supplying the temperature adjustment gas from the internal temperature adjustment block into the interior space after a heating of the substrates by the temperature adjustment furnace is stopped.

11. The heat treatment apparatus according to claim 10, wherein a temperature adjustment space is formed between the temperature adjustment furnace and the processing container, and the temperature adjustment furnace includes an external distribution unit including a gas pipe that distributes a cooling gas in the temperature adjustment space, and
during the temperature lowering process, the controller performs supplying the temperature adjustment gas into the interior space by the internal temperature adjustment block and distributing the cooling gas in the temperature adjustment space by the external distribution unit.

12. A temperature regulation method comprising:
(a) providing a heat treatment apparatus equipped with a processing container having an interior space in which substrates are processed;
(b) heating the substrates accommodated in the interior space from an outer side of the processing container by a temperature adjustment furnace disposed around the processing container; and
(c) moving an internal temperature adjustment block relative to the processing container to dispose the internal temperature adjustment block to face an opening that opens the interior space; and
(d) in a state where the internal temperature adjustment block is disposed facing the opening, supplying a temperature adjustment gas for regulating a temperature of the processing container into the interior space.
